(19) United States
(12) Patent Application Publication
(10) Pub. No.: US 2026/0133231 A1
(43) Pub. Date: May 14, 2026

(54) SINGLE PIN IMPEDANCE MEASUREMENT SYSTEM AND PHASE OFFSET COMPENSATION FOR A SINGLE PIN IMPEDANCE MEASUREMENT SYSTEM

(71) Applicant: Renesas Electronics America Inc., Milpitas, CA (US)

(72) Inventors: Norbert GREITSCHUS, Nabern (DE); Thomas SCHUERMANN, Munich (DE)

(73) Assignee: Renesas Electronics America Inc., Milpitas, CA (US)

(21) Appl. No.: 18/999,603

(22) Filed: Dec. 23, 2024

(30) Foreign Application Priority Data
Nov. 11, 2024 (GB) 2416584.7

(51) Int. Cl. G01R 27/16

(52) U.S. Cl. CPC G01R 27/16

(57) ABSTRACT

An impedance measurement system including: a signal generator including a memory and arranged to generate a digital test signal and at least one digital demodulation signal based on the memory, wherein the digital test signal has a first frequency and the at least one digital demodulation signal has the first frequency; a single pin for providing to a Device Under Test (DUT), an analogue test signal based on the digital test signal and measuring, in response to providing the analogue test signal to the DUT, an analogue input signal; and a demodulator configured to obtain: a first filtered digital signal based on the input signal; and the at least one digital demodulation signal to produce at least one digital demodulated signal indicative of the impedance.

### CROSS-REFERENCE TO RELATED APPLICATION

This application claims priority under 35 U.S.C. § 119 to UK Patent Application No. 2416584.7, filed on Nov. 11, 2024. The entire disclosure of UK Patent Application No. 2416584.7 is incorporated by this reference.

### FIELD OF THE INVENTION

The present disclosure relates to a single pin impedance measurement system and phase offset compensation for a single pin impedance measurement system, in particular, but without limitation, to a single pin impedance measurement system comprising a phase offset compensator configured to introduce an address offset in order to compensate for an unknown phase offset. The single pin impedance measurement system may be used with a steering device for a vehicle to implement a gesture-based human-machine interface system.

### DESCRIPTION OF RELATED ART

To measure or calculate the impedance of an external Device Under Test, DUT, a system may generate measurement values representing the amplitude and phase (or real- and imaginary-part) of the impedance. To reduce number of signal pins, only one connection per DUT should be used for providing a “test-signal” to the DUT and measuring the results.

A voltage may be applied to a DUT and the system may determine the impedance of the DUT by measuring the amplitude and the phase of the current which passes through the DUT. Alternatively, a current may be applied to the DUT and then the voltage can be measured across it to determine the amplitude and the phase of the voltage signal.

To be able to measure the real- and imaginary-parts of a signal influenced by a complex DUT, the test-signal must be a time variant signal, for example a signal-pulse or sinusoidal wave.

Typically, a sine wave is used, as it exhibits both an amplitude and phase (real- and imaginary-part: “Re” & “Im”).

Known systems typically implement an I/Q demodulator to derive Re and Im. The amplitude and phase of the current is measured by demodulating the signal measured across the DUT (either the current through the DUT or the voltage across the DUT) using the I/Q demodulator. This measurement is performed by multiplying the measured signal with a sine signal and a cosine signal of the same frequency. The output of the I/Q demodulator (after filtering) results in an in-phase, quadrature signal at DC. The output is complex, comprising a real component and an imaginary one. The amplitude is then given by \sqrt{Re²+Im²} and the phase is given by arctan (Im/Re).

Known systems have limited sensitivity, making it more susceptible to noise and parasitic, thus decreasing the accuracy and reliability of the measurement results.

Furthermore, due to internal signal delays which may be caused by either the frequency dependent signal processing of the analog amplifiers (similar to a filter function) used in the systems which measure impedance or by propagation delay in the digital processing, a phase shift may be introduced that is not related to the DUT. For example, delays created by mixed signal devices such as analog-to-digital converters that are in line with the signal processing path. Therefore, the output from the I/Q demodulator may have a phase offset which is not related to the DUT.

It is an objective of the present disclosure to provide a single pin impedance measurement system for measuring the impedance of an external DUT which has increased sensitivity and thus decreased noise susceptibility and increased measurement accuracy. Furthermore, it is desirable to develop a system which can account for the phase offset, as correcting for the phase offset increases accuracy.

### SUMMARY

According to a first aspect of the disclosure, there is provided an impedance measurement system comprising a signal generator comprising a memory and arranged to generate a digital test signal and at least one digital demodulation signal based on the memory, wherein the digital test signal has a first frequency and the at least one digital demodulation signal has the first frequency, a single pin for providing to a Device Under Test, DUT, an analogue test signal based on the digital test signal and measuring, in response to providing the analogue test signal to the DUT, an analogue input signal, a demodulator configured to obtain a first filtered digital signal based on the input signal and the at least one digital demodulation signal to produce at least one digital demodulated signal indicative of the impedance.

According to a second aspect of the disclosure, there is provided a single pin impedance measurement system comprising: an oversampling analogue-to-digital converter; a digital demodulator coupled to the analogue-to-digital-converter; and a memory configured to generate a test signal and one or more demodulation signals; wherein the test signal and the one or more demodulation signals are coherent such that the single pin impedance measurement system can take a phase measurement and an amplitude measurement of an impedance signal simultaneously.

According to a third aspect of the invention, there is provided a single pin impedance measurement system comprising: an oversampling analogue-to-digital converter; a digital demodulator coupled to the analogue-to-digital converter; a memory configured to generate a test signal and one or more demodulation signals; and a phase offset compensator; wherein the phase offset compensator is configured to introduce an address offset to the one or more demodulation signals and/or the test signal such that the an unknown phase offset between the test signal and the one or more demodulation signals is compensated for.

It will be appreciated that the single pin impedance measurement system of the third aspect may include providing and/or using features set out in the second aspect and can incorporate other features as described herein.

### BRIEF DESCRIPTION OF THE DRAWINGS

The disclosure is described in further detail below by way of example only with reference to the accompanying drawings, in which:

FIG. 1 is an impedance measuring system according to the prior art;

FIG. 2 is an example embodiment of a single pin impedance measurement system in accordance with the present disclosure.

FIG. 3 is a further example embodiment of a single pin impedance measurement system according to the present disclosure in greater detail;

FIG. 4 is an example embodiment of a single pin impedance measurement system in accordance with the present disclosure arranged to compensate for a phase offset;

FIG. 5 is an example embodiment of a steering device which uses the single pin impedance measurement system of the present disclosure; and

FIG. 6 is a table comparing the performance of the single pin impedance measurement system of the present disclosure with the prior art.

FIG. 7 is another embodiment of a single pin impedance measurement in accordance with the present disclosure.

### DETAILED DESCRIPTION

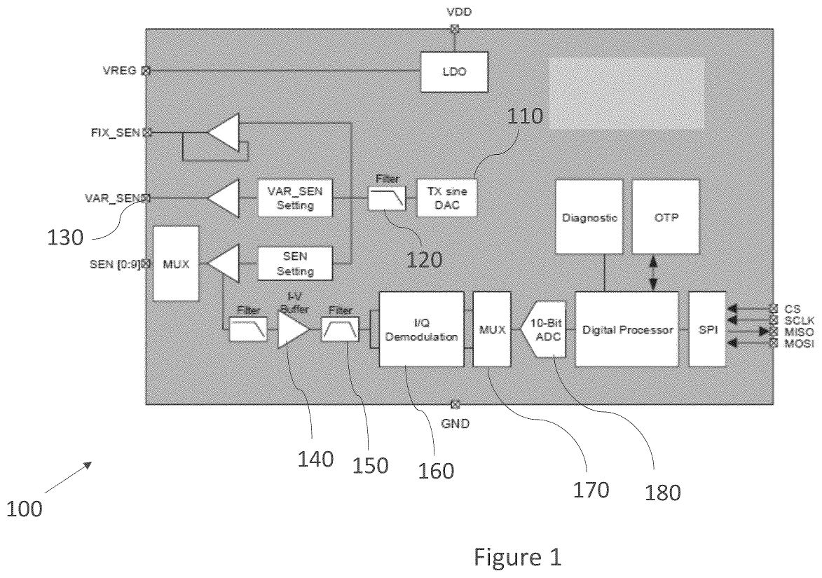

FIG. 1 is a circuit diagram of an impedance measuring system 100 according to the prior art. The system 100 comprises a sine wave generating digital-to-analog converter, TX-DAC, 110 coupled to a filter 120. The TX-DAC 110 and the filter 120 are configured to generate a sine wave signal at the pin 130 which is connected to the DUT.

The system 100 further comprises a voltage buffer amplifier, I-V Buffer, 140 coupled to a band pass filter 150. The I-V buffer 140 is configured to measure the current through the DUT, and the current signal is then filtered with by the band-pass filter 150 before being passed onto the I/Q Demodulation block 160. The I/Q Demodulation block 160 is configured to generate an I/Q demodulation signal by multiplying a sinusoidal signal input(f) measured at pin 130 with a SIN signal and a COS signal. This results in two signals being generated: input(f)×SIN(f) and input(f)×COS(f) which represent the real and imaginary part of the sinusoidal signal input(f). By measuring the real and imaginary part of the sine wave signal, the amplitude and phase of the signal can be calculated. The two signals (real signal and imaginary signal) are then passed onto the multiplexer (MUX) 170 which is configured to time interlace the signals. Finally, the time interlaced signal is passed to the analog-to-digital converter, ADC, 180.

The system 100 of the prior art has several disadvantages. Firstly, the I/Q Demodulation process is sensitive to the matching between SIN/COS. Any analog component in the system 100 might influence the matching due to process variation. Secondly, the I/Q Demodulation process is also sensitive to phase shift (i.e., delay) variation and to the sine wave signal from DAC 110. Any analog component variation in amplitude of the SIN signal and the COS signal influences the output of the I/Q Demodulation block 160. Thirdly, the real and imaginary signals are sent to ADC 180 via MUX 170 which time interlaces signal. Therefore, the acquisition time is doubled, and signal must be maintained at a constant level (only small changes in the signal allowed) between the two acquisition times to reduce error in the impedance measurement. Finally, the Bandpass filter 150 in front of I/Q Demodulation block 160 requires a stable bandpass characteristic in the analog domain. Furthermore, any changes in the frequency of the signal provided to filter 150 require corresponding changes to the bandpass filter. All of these disadvantages result in limited sensitivity in the system 100. Hence attempting to measure small changes in impedance with the system 100 becomes complex and expensive.

It is an objective of the present disclosure to overcome the limitations of the prior art.

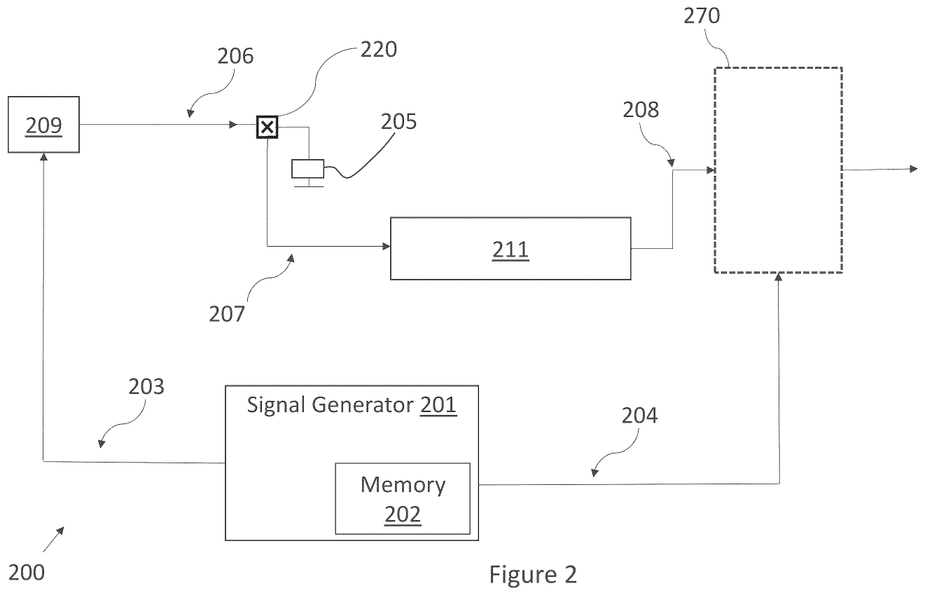

FIG. 2 is an example embodiment of a pin impedance measurement system 200 in accordance with the present disclosure. Impedance measurement system 200 may be coupled to an external system to obtain a clock signal with a system frequency fₛ (not shown). For example, the system frequency fₛ may be 32 MHz.

System 200 comprises a Signal Generator 201 and the Signal Generator 201 comprises a memory 202. Signal generator 201 is arranged to generate a test signal 203 based on the contents of memory 202.

Memory 202 comprises a look up table, LUT, storing a set of predefined values at respective memory addresses for generating the digital test signal 203.

In the example embodiment of FIG. 2, test signal 203 is a digital signal and therefore it will be referred to as digital test signal 203. In other embodiments, the Signal Generator 201 may comprise an integrated Digital to Analog converter such that after a test signal is generated an output of the Signal Generator 201 is an analog signal. Digital test signal 203 has a first frequency.

In the example embodiment of FIG. 2, impedance measurement system 200 further comprises a digital-to-analogue converter, DAC 209, coupled to the signal generator 201 to obtain the digital test signal 203 and generate at least one analogue test signal 206. The at least one analogue test signal 206 may be referred to as an excitation signal. In some embodiments, DAC 209 may operate at a second frequency, smaller than the system frequency fₛ, for example, 4 MHz. In some embodiments, DAC 209 may have a sampling frequency equal to the second frequency, such that DAC 209 has a sampling rate that is smaller than a system frequency fs.

In some embodiments, the at least one analogue test signal 207 has a frequency that is coherent to the system frequency fₛ. In some embodiments the at least one analogue test signal 206 has a frequency set by a fraction of the system frequency fₛ multiplied by a prime number. In some embodiments the frequency of the at least one analogue test signal 206 may be based on the product of a prime number and the system frequency fₛ. The prime number may be, for example, 7, 11, 13, 17, 19, . . . , etc. In some embodiments the frequency of the at least one analogue test signal 206 may be based on the length of the acquisition period of the DAC 206. In some embodiments the frequency of the at least one analogue test signal 206 may be given by the formula:

$${f}_{e x} = \frac{{f}_{s} \cdot N}{K}$$

where:
fₑₓ is the frequency of the analogue test signal 206, i.e. the excitation signal;
N is a prime number; and
K is the length of the acquisition period of DAC 209 in system clock cycles.

As an example to facilitate the understanding of the present disclosure, Table 1 shows the frequency of analogue test signal 206 for various prime numbers if one acquisition period has 4096 system clock cycles and the system frequency fₛ is equal to 30.72 MHz.

TABLE 1

| Prime Number | fₑₓ (KHz) |
|---|---|
| 7 | 52.5 |
| 11 | 82.5 |
| 13 | 97.5 |
| 17 | 127.5 |
| 19 | 142.5 |

Advantageously, reducing the sampling rate of the DAC 209 enables reducing the numbers of samples in the LUT, thus a smaller LUT is needed. This in turn results in corresponding reduction in the size of the memory and its power consumption, resulting in a more efficient system.

The impedance measurement system 200 is arranged to provide to a DUT 205 via a single pin 220 the at least one analogue test signal 206 to measure the impedance of DUT 205.

Signal Generator 201 is further arranged to generate at least one digital demodulation signal 204 based on the contents of memory 202. The at least one digital demodulation signal 204 may have the same frequency as the Digital test signal 203. In some embodiments, the at least one digital demodulation signal 204 may be coherent with the digital test signal 203.

Memory 202 comprises a look up table, LUT, storing a set of predefined values at respective memory addresses for generating the at least one digital demodulation signal 204. In other words, the LUT contains a number of samples for the digital demodulation signal amplitude values.

The at least one demodulation signal may comprise a first sinusoidal signal and a second sinusoidal signal (not shown) wherein the second sinusoidal signal is generated by phase sifting the first sinusoidal signal by 90 degrees.

Impedance measurement system 200 further comprises a single pin 220 for providing to the DUT 205, the analogue test signal SIG, 206, based on the digital test signal 203. In some embodiments there is no other connection or coupling between DUT 205 and impedance measurement system 200. In some embodiments, a ground plane may be coupled to both DUT 205 and impedance measurement system 200. Impedance measurement system 200 is configured to supply to or provide to the DUT 205 the at least one analogue test signal 206 and measure the influence of DUT on the at least one analogue test signal 206 via pin 220 and an input processing stage 211. Input processing stage 211 is coupled to the pin 220 and configured to obtain the analogue input signal 207 and generate a first filtered digital signal 208 based on the analogue input signal 207.

Impedance measurement system 200 further comprises a demodulator 270. Demodulator 270 is configured to obtain the first filtered digital signal 208 based on the analogue input signal 207 and the at least one digital demodulation signal 204 to produce at least one digital demodulated signal indicative of the impedance of DUT 205.

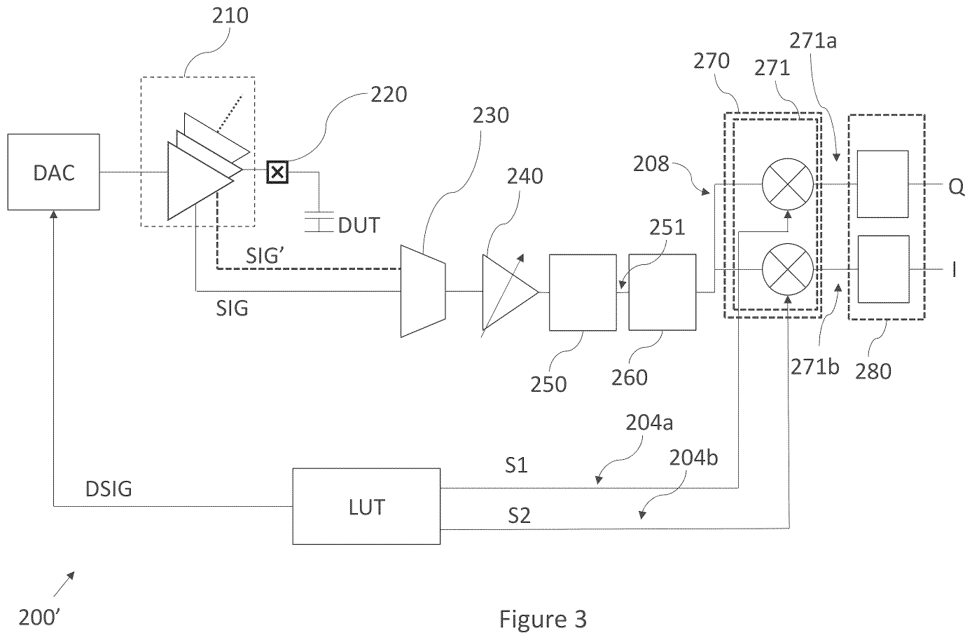

FIG. 3 is an example embodiment of a single pin impedance measurement system 200′ in accordance with the present disclosure. System 200″ further details a possible implementation of system 200. System 200″ includes, for example, further implementation details for the input processing stage 211 and the demodulator 270.

The system 200″ comprises a memory LUT configured to generate a digital base signal DSIG otherwise referred to as digital test signal 203. DSIG presents a test signal input to the system and may be an AC signal. In this embodiment, the DSIG may be a sinusoidal signal. The frequency of the DSIG signal may be adjustable based on system parameters. The DSIG can be thought of as a modulation signal.

Memory LUT may also generate a first signal S1 that may be a sine signal and a second signal S2 that may be a cos signal. Signals S1 and S2 may be AC signals. In the example embodiment of FIG. 2, they are sinusoidal signals, although in other embodiments they may be other type of signals such as pulse signals. Signals S1 and S2 can be thought of as de-modulation signals. Any of signals S1, S2 or the combination of signals S1 and S2 can be considered as the digital demodulation signal 204. In some embodiments, the DSIG and S1 and S2 signals may be synchronized.

The system 200 further comprises a digital-to-analogue converter, DAC, analogous to DAC 209 of FIG. 2. The DAC takes the base signal DSIG and converts it to an analogue signal. The DAC is coupled to one or more filters and buffers 210. The combination of the DAC and the one or more filters and buffers 210 are used to generate one or more time varying signals, which may also be referred to as a test signal, SIG, SIG′. The time varying signal(s) SIG, SIG′ obtained from pin 220 represent the DUT. Any of the signal(s) SIG, SIG′ or their combination may also be referred in this disclosure as analogue input signal 207.

The system 200 may also comprises a multiplexer 230 configured to combine the one or more time varying signals SIG, SIG′ into a single signal. In some embodiments multiplexer 230 is part of the input processing stage 211. In some embodiments analogue input signal 207 may be a single signal and therefore in such embodiments the system 200 may not comprise a multiplexer 230. This single signal is then passed through an amplifier 240.

Amplifier 240 is arranged to provide to an oversampling ADC 250 an amplified version of the analogue input signal 207. In some embodiments, amplifier 240 may be considered part of the input processing stage 211.

The system 200 comprises the analogue-to-digital, ADC, converter 250 which is configured to convert the signal received from the amplifier 240 to a digital signal that may be referred to as digital input signal 251. The ADC 250 is further configured to oversample the signal when performing the conversion. In some embodiments ADC 250 is part of the input processing stage 211.

Coupled to the ADC 250 is a filter 260, which may be, for example, a comb filter. Filter 260 is configured to filter the digital input signal 251 to generate the first filtered digital signal 208. In some embodiments filter 260 is part of the input processing stage 211.

The filtered digital signal is then passed through the demodulator 270. The demodulator may be, for example, an I/Q demodulator 271. In the example embodiment of FIG. 3 an input of the I/Q demodulator 271 is coupled to the output of filter 260, although in other embodiments that lack a filter 260 the I/Q demodulator 271 may be directly coupled to the output of ADC 250. In the example embodiment of FIG. 3, the demodulator is configured to multiply the filtered digital signal separately by the first signal to generate a real signal and by the second signal to generate an imaginary signal. In other words, the I/Q demodulator is configured to multiply the first filtered digital signal 208 with the first sinusoidal signal 204a to generate a real component signal 271a indicative of a real component of the analogue input signal 207 and multiply the first filtered digital signal 208 with the second sinusoidal signal to generate an imaginary component signal 271b indicative of an imaginary component of the analogue input signal 207. These signals are passed through an integrator 280 which is coupled to the output of the I/Q demodulator. The real and imaginary signals can then be used to calculate the amplitude and phase of the DUT. Thus, the at least one digital demodulated signal, indicative of the impedance of DUT 205, is based on the real component signal 271a and/or the imaginary component signal 271b.

In some embodiments, integrator 280 may have a frequency response with a notch at a frequency of at least one harmonic of the at least one demodulated signal, such that the integrator filters the real component signal 271a and the imaginary component signal 271b to generate the at least one digital demodulated signal.

In some embodiments, the memory may be, for example, a look-up table. A look up table is a hardware table which stores data. The data from the look-up table can be used directly in the DAC 209 for the generation of a test signal, for example digital test signal 203, or to generate the first signal S1 and the second signal S2, that is digital demodulation signal 204. In other embodiments, the memory may be other forms of hardware table in accordance with the understanding of the skilled person. As demodulation is performed in the digital domain, matching between first signal S1 and the second signal S2 is given per construction, a technique which is already known in the art. However, for system 200, the multiplication with the first signal S1 and the second signal S2 takes place at the same time with same signal, thereby using only one acquisition per result. This improves the performance of the system when compared to the prior art system of FIG. 1, where two samples are needed to process both the I and Q data (i.e., one for I and one for Q).

The ADC 250 is an over-sampling ADC, in this example embodiment, the ADC 250 is a sigma-delta ADC, for example, a 1-Bit, 2^{nd} order sigma delta ADC. In the example embodiment of FIG. 3, the ADC 250 operates at the system frequency fₛ, although in other embodiments it may operate at a frequency lower to the system frequency fₛ. In alternative embodiments, other types of over-sampling ADCs may be used in accordance with the understanding of the skilled person. As the system 200 uses an over-sampling ADC 250, a Bandpass filter is no longer required prior to the ADC conversion. Instead only a small anti alias low pass filter is needed due to the oversampling approach.

The test-signal, the first signal S1 and the second signal S2 used for the I/Q demodulation are based on the same digital signal DSIG generated by the memory LUT. Therefore, the phase difference is constant and independent of analog matching between the three signals.

The frequency of the test-signal is coherent with the first signal S1 and the second signal S2 (demodulation signals) and the number of signal periods is a prime number of the sampling signal. Therefore, all harmonics of the demodulated signals will be completely filtered out by the integrator 280. The integrator 280 in this example embodiment forms a comb filter with notches at all the harmonics. Therefore, a high precision analog filter in front of ADC 250 is not required. Additionally, the demodulation signals require a low number of samples per period which reduces the effort for the memory LUT. The lower the number of samples results in an increase in harmonics, but the system 200 is insensitive to harmonics due to the comb filter.

Similarly, for the test signal generation with a DAC, the sampling rate of the DAC can be reduced. This reduces the number of samples in the memory LUT and hence the area and power consumption of the system 200. The system 200 of the present disclosure is much less sensitive against harmonics.

The digital base signal DSIG may also be referred to as the modulation signal or the digital test signal. The first signal S1 and the second signal S2 may also be referred to collectively as the demodulation signals or the digital demodulation signal.

The modulation signal DSIG and demodulation signals S1, S2 provided by the LUT may be in phase. However, when the modulation signal DSIG passes through the system 200 from the LUT to the demodulator 270, a number of processing delays are introduced resulting in a phase offset between the modulation and demodulation signals.

There are several ways known in the art to correct or cancel the phase offset depending on what has caused the phase offset. For example, if the phase offset is known then it can be cancelled during the external I/Q processing. However, the phase offset is not always known, therefore errors may still be introduced. Alternatively, the phase offset may be due to digital processing. If this is the case, then the phase offset (latency) is defined by a number of z⁻¹ stages and can, therefore, be compensated by adding more z⁻¹ stages to result in a total phase shift of 360°. However, such a method results in the response time and the repetition rates being increased.

If the phase offset is introduced in the analogue signal process, a filter must be used which has a high enough band width such that the phase shift is negligible. For instance, the result error is less than 0.02%. This method results in a wide signal bandwidth and therefore the signal is highly sensitive noise. If, instead, the phase offset is due to a variation in an analogue property (for example due to process or temperature) then the phase offset can be cancelled by implementing a time-constant bandwidth trimming. Such a solution is complex, results in larger sizes of systems and longer development time. Alternatively, such a phase offset can be adjusted for by trimming the delay between the phase of the test signal and the sin and cos (demodulation) signals. However, the amplitude of the test signal and/or the demodulation signals must be kept constant which requires a tunable all pass filter which is expensive to implement and takes up a lot of room in the system.

Therefore, a new way to compensate for the phase offset of the input signal (the signal that will be entering the demodulator from the DAC) can be introduced by other factors such as cable harnesses and signal processing delays of the measurement circuit which accounts for the disadvantages of the prior art is required.

In the present disclosure, this phase offset is compensated for by introducing an offset compensation to the demodulation signals S1, S2 or the digital test signal 203. As such, in some embodiments the signal generator 201 is configured to adjust the phase of the at least one digital demodulation signal 204 and/or the digital test signal 203 to correct a phase offset between the first filtered digital signal 208 and the at least one digital demodulation signal 204.

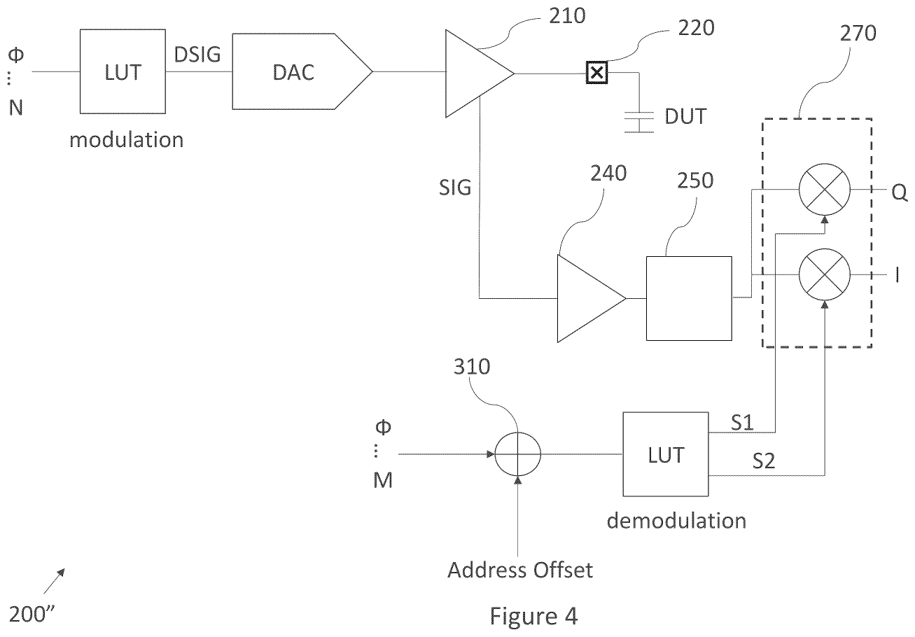

FIG. 4 is an example embodiment of phase offset compensation for the single pin impedance measurement system 200″ according to the present disclosure. The system 200″ of FIG. 4 is the same as the system 200′ of FIG. 3, except some features have been removed to make the system easier to read/understand. All features that are the same between FIG. 3 and FIG. 4 have been given the same labels and are taken to have the same meaning and functionality as they do for FIG. 3.

The LUT in FIG. 4 is shown as two separate elements, one for the modulation signal DSIG and one for the demodulation signals, S1 and S2. This has been done for ease of understanding. The phase offset compensation of the example embodiment of FIG. 4 is only added to the demodulation signals S1 and S2, therefore splitting the LUT in this way in FIG. 4 allows for this to be seen.

The phase offset compensation is realised by adding an address offset to the part of the LUT that generates the demodulation signals S1 and S2.

Demodulation 270 in system 200″ is realized in digital domain. The modulation and demodulation signals are based on the memory LUT. In the LUT, the first signal (or the second signal) is realized. The LUT output is connected to the DAC which generates the test signal also referred to as the analog test signal. The LUT output is also connected to the demodulator 270. The modulation signal DSIG values and the demodulation signal S1, S2 values will be read out of the memory LUT with a rotating address. A phase offset compensation is realized by adding an “address offset” to the demodulation signal (S1, S2) LUT address. Thus the “address offset” directly translates to a phase offset for any of the signals generated by the Signal Generator 201. In this manner Signal Generator 201 may adjust the phase of the at least one digital demodulation signal 204 and/or the digital test signal 203 by adding an address offset to a part of the LUT that generated the at least one digital demodulation signal and/or the digital test signal.

For example, if the LUT contains N samples for the demodulation signal S1, S2 amplitude numbers. The “address counter” will wrap at the end and hence continuous demodulation signals S1, S2 are generated. When the LUT for the modulation signal DSIG and the demodulation signals S1, S2 starts with address “0”, the phase is 0° between the modulation signal DSIG and the first signal S1. The phase is 90° between the modulation signal DSIG and the second signal S2 for address “0”, because the second signal S2 is generated by phase shifting S1 by 90 degrees, or in other words by using the later or earlier addresses in the LUT that would correspond to a phase offset of 90 degrees. The address offset defines how much additional phase offset will be added between the modulation signal DSIG and the demodulation signals S1, S2.

The address offset can be generated in a number of different ways. A few ways to generate the address offset are given below, however this is not an exhaustive list of the ways to generate the address offset. There will be other ways in accordance with the understanding of the skilled person.

The address offset can be given from an external system, for example an external microcontroller unit and can be updated at any time during use of the single pin impedance measurement system 200.

Alternatively, impedance measurement system 200 may be configured to determine the address offset internally during a calibration phase. In the calibration phase, the single pin impedance measurement system 200 has to be connected to a DUT formed by a capacity load only. When this condition is satisfied, the expected phase between voltage and current is defined (90°). The demodulation I/Q data will be processed and the address offset will be changed with processing during calibration phase so that the measured phase difference between voltage and current as expressed by the output of the demodulator 270 becomes equal to 90°. This can be done with either, for example, a simple counter or an algorithm such as, for example, a CORDIC algorithm. When the I-Output of the demodulator becomes minimal, the corresponding address offset is the value required to compensate the phase offset of the signal processing.

As mentioned above, the phase offset may be caused by a variation in an analogue property (for example due to process or temperature) of the system 200. In some embodiments, impedance measurement 200, 200′ and/or 200″ may comprise a temperature sensor (not shown), communicatively coupled to the Signal Generator 201. In such embodiments, memory 202 may comprise a set of predefined address offset values for respective values of temperature. Thus, the Signal Generator may obtain a temperature measurement and generate the digital test signal 203 and/or the digital demodulation signal 204 based on the values stored in the LUT for the corresponding value of temperature.

As mentioned above, the address offset can also be implemented in the LUT for the modulation signal instead of in the demodulation signals. However, the second order effects of the address offset for the demodulation signals are more reliable because analog settling times are not relevant when the signal starts with different phase. Therefore it is preferable to implement the address offset in the demodulation signals.

The phase offset compensation as described above may be used with a single pin impedance measurement system which is described in further detail below.

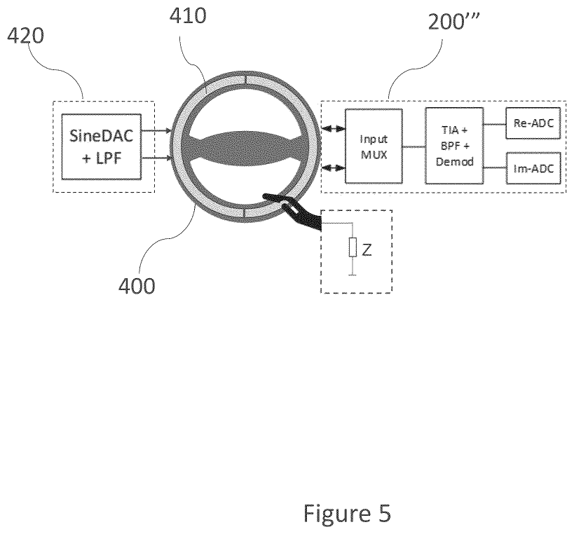

FIG. 5 is an example embodiment of a steering device 400 for which a system 200″ for measuring impedance can be used according to the present disclosure. The system 200″ has the same architecture as the system 200 of FIG. 2, although in some cases it may have the architecture of system 200′ of FIG. 3 or 200″ of FIG. 4. The steering device 400 comprises one or more sensors 410. The steering device 400 may be, for example, a steering wheel for a car. In other embodiments, the steering device 400 may be integrated with other types of vehicles in accordance with the understanding of the skilled person.

In the example embodiment of the steering device 400 the one or more sensors are one or more conductive foils (not shown). As explained below, the single pin of the impedance measurement system is coupled to the one or more sensors 410 integrated in the steering wheel 400 for a vehicle, wherein the impedance measurement system is configured to drive the one or more sensors to detect contact of an operator with the steering wheel. Each of the conductive foils are driven by a sine wave signal generated by the integrated circuit 420. The system 200″ is configured to measure a current and a phase shift across the conductive coils in order to measure the impedance.

In operation, a pressure motion asserted by an operators hands causes the ground capacity across the conductive foil to increase thus adding resistance Z to the sensors 410. An application example includes sensors located on different positions of a steering device 400. This allows the operator to input various commands through hand gestures and hand position while maintaining contact with the steering device 400. Examples of control functions may include cruise control settings, and infotainment functions.

In an exemplary embodiment of the steering device 400 comprising the system 200′″ for measuring impedance, the following set-up may be used. The system 200′″ and ADC 250 have a frequency fs which may be, for example, 32 megahertz. The ADC 250 is a 1-Bit ADC implemented as an oversampling sigma delta. The ADC 250 operates at the system frequency fs. The ADC 250 out is decimated with decimation filter to provide a 1 megahertz (1:32) sampling rate. In such an exemplary embodiment, 128 decimated samples will integrated (accumulated) after demodulation.

In this exemplary embodiment, the DAC may operate at an eighth of the system frequency fs. For example, if the system frequency is 32 megahertz, then the DAC will operate at 4 megahertz. The DAC, in this exemplary embodiment, is configured to generate test signals up to ˜150 kilohertz. The exemplary system 200″ uses 5 memories (in this particular example, they are look-up tables) and, as such, 5 different frequencies can be selected. The low pass filter 240 for DAC output can be relaxed due to the oversampling approach. The low pass filter 240 in front of ADC 250 can be generated with relatively simple architectures as only very spurious tones need be filtered out due to the ˜200× oversampling. The bandwidth can be relatively high and therefore the impact due to delay variation by using low frequency filters is reduced.

In this exemplary embodiment, the test signal frequency is coherent to the system clock frequency. The test signal frequencies are set by prime numbers of a divided system clock. For example, if one acquisition period has 4096 system clock cycles, the test signal-frequency (which is stored in the memory) will be fs/4096×Prime, where Prime may be one of 7, 11, 13, 17, 19 and so on.

The resolution of the above exemplary system 200″ for measuring impedance is 16 Bit without any signal averaging and the system 200″ has a fast acquisition time (<200 μs).

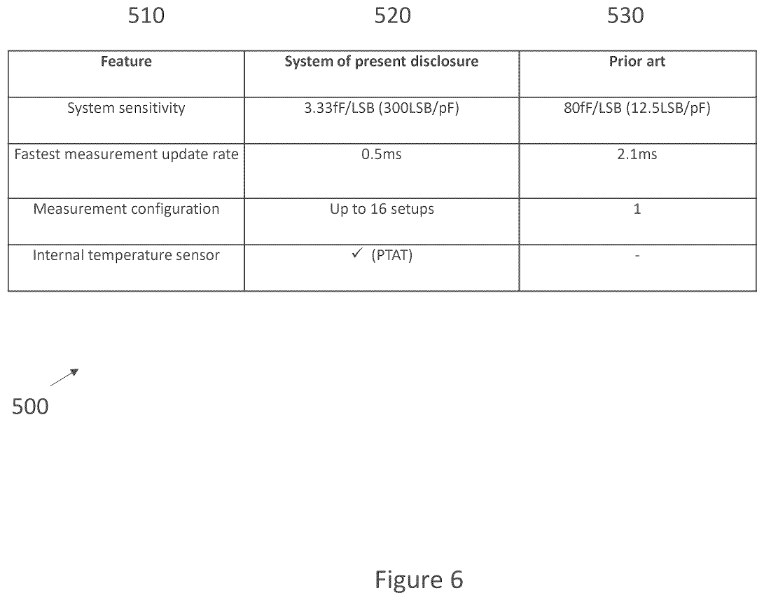

FIG. 6 is a table 500 comparing the performance of the exemplary system 200″ with a system of the prior art. Column 510 lists a number of features that the two systems will be compared for, column 520 contains the data for the exemplary system 200″ of the present disclosure and column 530 contains the data for the system of the prior art.

As can be seen from the table, the exemplary systems 200″ of the present disclosure has a sensitivity which is 16× higher with comparable chip costs (chip size) at comparable power consumption. The exemplary system 200 also has an acquisition time which is 4.5× faster than the system of the prior art. Finally, the resolution of the exemplary system 200′″ is 16 Bit without further averaging (for noise reduction averaging is possible), whereas the system of the prior art has 10 Bit resolution without averaging.

It will be appreciated that the single pin impedance measurement system of the present disclosure may be a system for measuring the impedance for a steering device for a vehicle in order to implement a gesture-based human-machine interface system for the vehicle. However, the single pin impedance measurement system may be implemented in other types of devices or architectures that require measuring an impedance in accordance with the understanding of the skilled person.

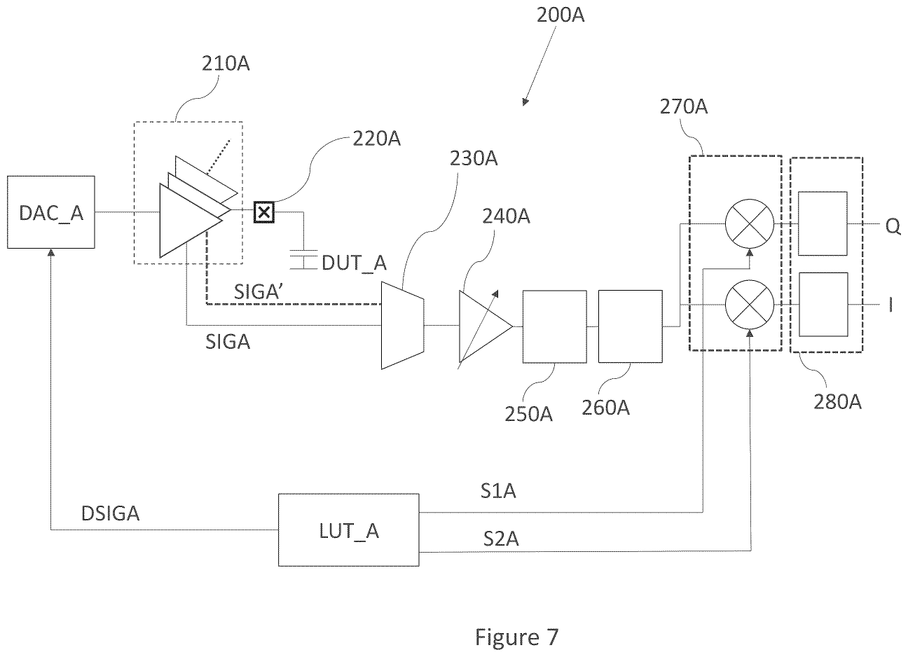

FIG. 7 is another embodiment of a single pin impedance measurement system 200A in accordance with the present disclosure. The system 200A comprises a memory LUT_A configured to generate a digital base signal DSIGA. DSIGA presents a test signal input to the system and may be an AC signal. In the present embodiment it may be a sinusoidal signal. The frequency of the DSIGA signal may be adjustable based on system parameters. The DSIGA can be thought of as a modulation signal. Signal S1A may be a sine signal and the second signal S2A may be a cos signal. Signals S1A and S2A may be AC signals. In the present embodiment, they may be sinusoidal signals. Signals S1A and S2A can be thought of as de-modulation signals. In some embodiments, the DSIGA and S1A and S2A signals may be synchronized. As described above, in some embodiments, a phase delay can be added to the S1A and S2A signals as to correct for signal processing delays not related to DUT_A. For example, signal processing delay introduced by analogue-to-digital (ADC) converter 250A. The system 200A further comprises a digital-to-analogue converter (DAC_A) which takes the base signal DSIGA and converts it to an analogue signal. The DAC_A is coupled to one or more filters and buffers 210A. The combination of the DAC_A and the one or more filters and buffers 210A are used to generate one or more time varying signals, which may also be referred to as a test signal, SIGA, SIGA′. The time varying signal(s) SIGA, SIGA′ represent the DUT_A at pin 220A.

The system 200A may also comprises a multiplexer 230A configured to combine the one or more time varying signals SIGA, SIGA′ into a single signal. This single signal is then passed through an amplifier 240A.

The system 200A comprises an analogue-to-digital (ADC) converter 250A which is configured to convert the signal received from the amplifier 240A to a digital signal. The ADC 250A is further configured to oversample the signal when performing the conversion. Coupled to the ADC 250A is a filter 260A, which may be, for example, a comb filter. The filtered digital signal is then passed through the demodulator 270A. The demodulator may be, for example, an I/Q demodulator. The demodulator is configured to multiple the filtered digital signal separately by the first signal to generate a real signal and by the second signal to generate an imaginary signal. These signals are passed through an integrator 280A. The real and imaginary signals can then be used to calculate the amplitude and phase of DUT_A.

In some embodiments, the memory may be, for example, a look-up table. A look up table is a hardware table which stores data. The data from the look-up table can be used directly in DAC_A for the generation of a test signal or in the demodulator to generate the first signal S1A and the second signal S2A. In other embodiments, the memory may be other forms of hardware table in accordance with the understanding of the skilled person.

As demodulation is performed in the digital domain, matching between first signal S1A and the second signal S2A is given per construction, a technique which is already known in the art. However, for system 200A, the multiplication with the first signal S1A and the second signal S2A takes place at same time with same signal, thereby using only one acquisition per result.

The ADC 250A is an over-sampling ADC, in this example embodiment, the ADC 250A is a sigma-delta ADC, for example, a 1-Bit, 2^{nd} order sigma delta ADC. In alternative embodiments, other types of over-sampling ADCs may be used in accordance with the understanding of the skilled person. As the system 200A uses an over-sampling ADC 250A, a Bandpass filter is no longer required prior to the ADC conversion. Instead only a small anti alias low pass filter is needed due to the oversampling approach.

The test-signal, the first signal S1A and the second signal S2A used for the I/Q demodulation are based on the same digital signal DSIGA generated by the memory LUT_A. Therefore, the phase difference is constant and independent of analog matching between the three signals.

The frequency of the test-signal is coherent with the first signal S1A and the second signal S2A (demodulation signals) and the number of signal periods is a prime number of the sampling signal. Therefore, all harmonics of the demodulated signals will be completely filtered out by the integrator 280A. The integrator 280A in this example embodiment forms a comb filter with notches at all the harmonics. Therefore, a high precision analog filter in front of ADC 250A is not required. Additionally, the demodulation signals require a low number of samples per period which reduces the effort for the memory LUT_A. The lower the number of samples results in an increase in harmonics, but the system 200A is insensitive to harmonics due to the comb filter.

Similarly, for the test signal generation with DAC_A, the sampling rate of the DAC_A can be reduced. This reduces the number of samples in the memory LUT_A and hence the area and power consumption of the system 200A.

The system 200A of the present disclosure is much less sensitive against harmonics.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

What is claimed is:

1. An impedance measurement system comprising:
a signal generator comprising a memory and arranged to generate a digital test signal and at least one digital demodulation signal based on the memory, wherein the digital test signal has a first frequency and the at least one digital demodulation signal has the first frequency;
a single pin for providing to a Device Under Test (DUT), an analogue test signal based on the digital test signal and measuring, in response to providing the analogue test signal to the DUT, an analogue input signal; and
a demodulator configured to obtain:
a first filtered digital signal based on the input signal; and
the at least one digital demodulation signal
to produce at least one digital demodulated signal indicative of the impedance.

2. The impedance measurement system of claim 1, wherein the at least one demodulation signal comprises a first sinusoidal signal and a second sinusoidal signal wherein the second sinusoidal signal is generated by phase shifting the first sinusoidal signal by 90 degrees.

3. The impedance measurement system of claim 1, further comprising an input processing stage coupled to the single pin and to the demodulator and configured to obtain the analogue input signal and generate the first filtered digital signal based on the analogue input signal.

4. The impedance measurement system of claim 3, wherein the input processing stage comprises an oversampling ADC configured to generate a digital input signal based on the analogue input signal.

5. The impedance measurement system of claim 4, wherein the oversampling ADC is a 1-bit Sigma Delta ADC operating at a system frequency fs.

6. The impedance measurement system of claim 4, wherein the input processing stage comprises a filter configured to filter the digital input signal to generate the first filtered digital signal.

7. The impedance measurement system of claim 4, wherein the input processing stage comprises an amplifier, configured to provide to the oversampling ADC an amplified version of the analogue input signal.

8. The impedance measurement system of claim 4 wherein the demodulator comprises an I/Q demodulator coupled to an output of the oversampling ADC, the I/Q demodulator being configured to:
multiply the first filtered digital signal with the first sinusoidal signal to generate a real component signal indicative of a real component of the analogue input signal; and
multiply the first filtered digital signal with the second sinusoidal signal to generate an imaginary component signal indicative of an imaginary component of the analogue input signal,
wherein the at least one digital demodulated signal is based on the real component signal and/or the imaginary component signal.

9. The impedance measurement system of claim 8 further comprising
an integrator coupled to the output of the I/Q demodulator, wherein the integrator comprises a frequency response with one notch at a frequency of at least one harmonic of the at least one demodulated signal,
wherein the integrator is configured to filter the real component signal and the imaginary component signal to generate the at least one digital demodulated signal.

10. The impedance measurement system of claim 1, further comprising a digital-to-analogue converter, DAC, coupled to the signal generator to obtain the digital test signal and generate the at least one analogue test signal.

11. The impedance measurement system of claim 10, wherein the DAC has a sampling rate that is smaller than a system frequency fs.

12. The impedance measurement system of claim 11, wherein the at least one analogue test signal has a frequency set by a fraction of the system frequency fs multiplied by a prime number.

13. The impedance measurement system of claim 12, wherein the DAC is coupled to one or more filters and/or one or more buffers configured to obtain an output from the DAC and generate the at least one analogue test signal.

14. The impedance measurement system of claim 1, wherein the memory comprises a look up table, LUT, storing a set of predefined values at respective memory addresses for generating the digital test signal and the at least one digital demodulation signal.

15. The impedance measurement system of claim 14, wherein the signal generator is configured to adjust the phase of the at least one digital demodulation signal and/or the digital test signal to correct a phase offset between the first filtered digital signal and the at least one digital demodulation signal.

16. The impedance measurement system of claim 15, wherein the signal generator adjusts the phase of the at least one digital demodulation signal and/or the digital test signal by adding an address offset to a part of the LUT that generated the at least one digital demodulation signal and/or the digital test signal.

17. The impedance measurement system of claim 16, wherein the signal generator is configured to obtain the address offset from an external system to the impedance measurement system.

18. The impedance measurement system of claim 16, further configured to determine the address offset during a calibration phase, wherein the calibration phase comprises coupling to the single pin a DUT comprising only a capacitive load.

19. The impedance measurement system of claim 16, wherein the memory comprises a set of predefined address offset values for respective values of temperature.

20. The impedance measurement system of claim 1, wherein the single pin is coupled to one or more sensors integrated in a steering wheel for a vehicle, wherein the impedance measurement system is configured to drive the one or more sensors to detect contact of an operator with the steering wheel.
